(19) United States
(12) Patent Application Publication
(10) Pub. No.: US 2016/0174421 A1
(43) Pub. Date: Jun. 16, 2016

(54) METAL TEXTURE COATING FOR TRANSMITTING ELECTRIC WAVE AND MANUFACTURING METHOD THEREOF

(71) Applicants: Hyundai Motor Company, Seoul (KR); Kia Motors Corporation, Seoul (KR)

(72) Inventors: So Jung Shim, Seoul (KR); Byung Kyu Cho, Seoul (KR); Seung Chan Hong, Seongnam (KR)

(21) Appl. No.: 14/715,142

(22) Filed: May 18, 2015

(30) Foreign Application Priority Data
Dec. 10, 2014 (KR) 10-2014-0177814

(51) Int. Cl. H05K 9/00; C23C 16/44; B60R 13/00; C23C 16/06

(52) U.S. Cl. CPC H05K 9/0098; C23C 16/06; C23C 16/44; B60R 13/00

(57) ABSTRACT

Disclosed herein are a metal texture coating for transmitting an electric wave and a manufacturing method thereof The metal texture coating for transmitting an electric wave includes: a transparent resin film; a metal texture layer deposited on any one of both surfaces of the resin film; and a chromium oxide layer deposited on the metal texture layer so as to transmit the electric wave therethrough and protect the metal texture layer.

### CROSS REFERENCE TO RELATED APPLICATION

The present application claims priority to Korean Patent Application No. 10-2014-0177814, filed Dec. 10, 2014, the entire contents of which is incorporated herein for all purposes by this reference.

### TECHNICAL FIELD

The present invention relates to a metal texture coating for transmitting an electric wave and a manufacturing method thereof The metal texture coating for transmitting an electric wave may transmit the electric wave and provide a metal texture.

### BACKGROUND OF THE INVENTION

In accordance with the need for improvement of quality of interior and exterior materials for a vehicle, research into use of a paint containing real metals or metal particles has been conducted. However, when the metal is used in a portion in which transmission and reception of an electromagnetic wave are required, reception sensitivity may be decreased due to an electromagnetic wave blocking effect of the metal itself to thereby deteriorate performance, such that an applicable field has been limited. Therefore, a technology of forming a metal material such as tin, indium, or the like, that may transmit the electromagnetic wave and coating a protecting layer in order to provide a metal texture of a polymer material and promote securing of transmitting and receiving properties of the electromagnetic wave has been developed.

According to the related art, a transparent oxide of silicon, titanium, zirconium, or the like, has been used as a material external corrosion may be prevented and abrasion resistance may be improved of a protecting layer in a tin or indium compound. However, substantial amount of tin or indium compound may be required for suitable thickness, which may be disadvantageous.

However, in the present invention, a chromium oxide may implement a metal texture from tin or indium and serve as a protecting layer or material, thereby to implement greater metal texture by depositing the tin or the indium at a reduced thickness.

Although chromium, which is a metal having excellent conductivity, has an electromagnetic wave blocking property, the chromium may transmit and receive electromagnetic wave via adjusted thickness and a change in a composition such as an oxide, such that it may be used as the material of the protecting layer.

### SUMMARY OF THE INVENTION

Thus, in preferred aspects, the present invention provides a metal texture coating and a manufacturing method thereof. In particular, the metal texture coating may be a chromium oxide for transmitting an electric wave as such a metal texture layer may be protected. According to an exemplary embodiment of the present invention, provided is a metal texture coating for transmitting an electric wave that may include: a transparent resin film; a metal texture layer deposited on any one of both surfaces of the resin film; and a chromium oxide layer deposited on the metal texture layer so as to transmit the electric wave therethrough and protect the metal texture layer.

The term “transparent” material or “transparent” resin, as used herein, may refer to a material having substantial transmittance of a fraction of light, such as visible light. For instance, substantial amount of visible light such as of about 50%, about 60%, about 70%, about 80%, about 90%, about 95%, about 99%, or greater thereof may transmit or pass through the transparent material or resin.

The metal texture layer may be formed of one or more of tin and indium and have a thickness of about 150 nm or less.

The chromium oxide layer may have a thickness of about 1.0 μm or less.

A hair line may be formed on any one of both surfaces of the resin film. For instance, the hair line may be formed on the surface where the metal texture layer is deposited or on the surface opposite to the metal texture layer.

The metal texture coating for transmitting an electric wave may further include a protecting layer formed on the chromium oxide layer.

According to another exemplary embodiment of the present invention, provided is a manufacturing method of a metal texture coating for transmitting an electric wave. The method may include: a step of installing a transparent resin film in a chamber for deposition; a step of forming argon and nitrogen atmospheres using a process gas within the chamber in which vacuum is formed; a first depositing step of depositing a metal texture layer on any one of both surfaces of the resin film; a step of discharging a residual material generated during the first depositing step and forming argon, nitrogen, and oxygen (O₂) atmospheres using a process gas within the chamber in which the vacuum is formed; and a second depositing step of depositing a chromium oxide layer on the metal texture layer.

In the first depositing step, the metal texture layer may be formed of one or more of tin and indium and be formed at a thickness of about 150 nm or less.

In the second depositing step, the chromium oxide layer may be formed at a thickness of about 1.0 μm or less.

In the second depositing step, a ratio of the oxygen (O₂) to the process gas may be about 7 mol% or greater.

The manufacturing method of a metal texture coating for transmitting an electric wave may further include, before the step of installing the transparent resin film, a step of forming a hair line on any one of both surfaces of the resin film.

The manufacturing method of a metal texture coating for transmitting an electric wave may further include, after the second depositing step, a step of applying a protecting layer onto the chromium oxide layer.

Further provided are vehicle parts that comprise the metal texture coating as described herein.

Other aspects of the invention are disclosed infra.

### BRIEF DESCRIPTION OF THE DRAWINGS

FIG. 1 illustrates an exemplary metal texture coating for transmitting an electric wave according to an exemplary embodiment of the present invention.

FIG. 2 is an exemplary graph showing the differences in attenuation factor of the electric wave based on the thickness of chromium oxide layer.

FIG. 3 is an exemplary graph showing the differences in attenuation factor of the electric wave of chromium oxide layer in accordance with a ratio of oxygen (O₂) in the process gas in second depositing step.

FIG. 4 illustrates an exemplary deposition apparatus in an exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular exemplary embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

All terms including technical terms and scientific terms used herein have the same meaning as the meaning generally understood by those skilled in the art to which the present invention pertains unless defined otherwise. Terms defined in a generally used dictionary are additionally interpreted as having the meaning matched to the related art document and the currently disclosed contents and are not interpreted as ideal or formal meaning unless defined.

Hereinafter, a metal texture coating for transmitting an electric wave and a manufacturing method thereof according to an exemplary embodiment of the present invention will be described.

The metal texture coating for transmitting an electric wave may include: a transparent resin film 110; a metal texture layer 120 deposited on any one of both surfaces of the resin film 110; and a chromium oxide layer 130 deposited on the metal texture layer 120 so as to transmit an electric wave therethrough and protect the metal texture layer 120.

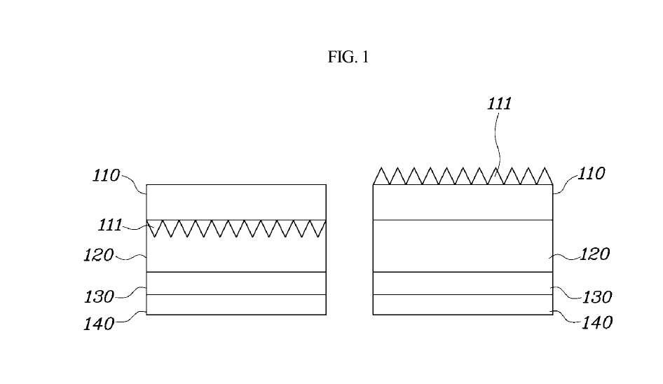

As illustrated in FIG. 1, the resin film 110, which may be any types of generally used transparent plastic film in the related art, may be positioned at the outermost layer of the metal texture coating for transmitting an electric wave according to an exemplary embodiment of the present invention. Indeed, the resin film may serve to protect the entirety of the metal texture coating. As a material of the resin film 110 used as described above, a material such as polycarbonate (PC), polyethylene terephthalate (PET), or the like, may be used. The metal texture layer 120 may be a layer for showing a metal texture as represented by a name. The metal texture layer 120 may be formed instead of an actual metal that does not transmit an electric wave therethrough, as such the metal texture layer 120 may provide a metal appearance to the metal texture coating without deteriorating a transmission property of the electric wave. In particular, indium or tin may be used as a material of the metal texture layer 120. Finally, the chromium oxide layer 130 may be a layer for protecting the metal texture layer 120. In the related art, a chromium oxide has been used in order to block the electric wave. However, in the present invention, the chromium oxide layer 130 may have electric wave transmission performance while maintaining a protecting function. Particularly, the chromium oxide layer 130 has unique gloss property, thereby enhancing the metal texture shown in the metal texture layer 120. Therefore, the metal texture layer 120 may be implemented at a reduced thickness as compared with the related art. For example, the metal texture layer 120 may be formed of one or more from tin and indium and may have a thickness of about 150 nm or less.

The metal texture layer 120 formed of the tin and the indium may provide the metal texture even at a thickness of at most of about 150 nm due chromium oxide layer 130 that enhances the metal texture, as described above. Therefore, unlike the related art in which the tin or the indium is deposited at a thickness of about 200 nm or greater, the metal texture may be maintained at a decreased thickness in the present invention.

Further, the chromium oxide layer 130 may have a thickness of about 1.0 μm or less.

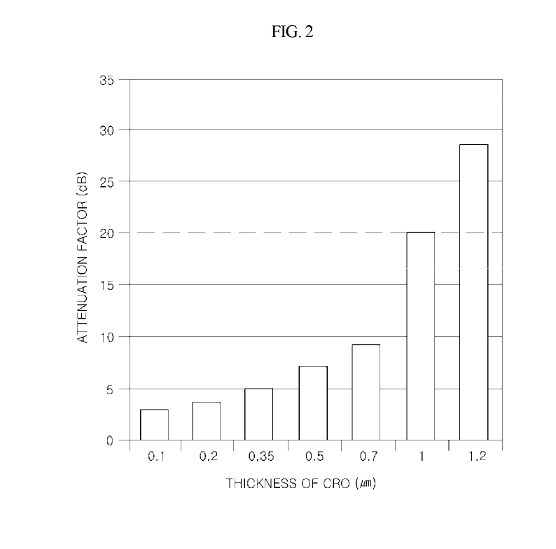

As shown in FIG. 2, a thickness of the chromium oxide layer 130 and an attenuation factor of the electric wave are in proportion to each other. When the chromium oxide layer 130 has a thickness of about 1.0 μm or less, a attenuation factor may be 20 dB or less, such that transmitting and receiving the electric wave may not be deteriorated. Therefore, corrosion resistance of the chromium oxide may be secured while maintaining the transmission property of the electric wave.

Further, a hair line 111 may be formed on any one of both surfaces of the resin film 110. For example, the hair line 111 may be formed on a surface on which the metal texture layer is deposited or a surface opposite to the metal texture.

The hair line 111, as being formed in a thin line, may improve a texture of a surface on which it is formed. As shown in right of FIG. 1, the hair line 111 may be formed on an outer surface which is opposite to the metal texture layer 120, or alternatively, as shown in left of FIG. 1, the hair line 111 may be formed on an inner surface which is same surface of the metal texture layer 120 of the resin film 110, such that a texture may have improved luxuriousness. The hair line 111 may be formed simultaneously with the resin film 110 or be formed by performing post-processing on the manufactured resin film 110.

The metal texture coating for transmitting an electric wave may further include a protecting layer 140 applied to the chromium oxide layer 130.

Moreover, a transparent paint, such as an acryl paint, or the like, may be used as a material of the protecting layer 140. The protecting layer 140 may serve to improve entire durability of the coating as well as protect the chromium oxide layer 130 from an external environment.

A manufacturing method of a metal texture coating for transmitting an electric wave may include: a step of installing the transparent resin film 110 in a chamber 210 for deposition; a step of forming argon and nitrogen atmospheres using a process gas within the chamber 210 in which vacuum is formed; a first depositing step of depositing the metal texture layer 120 on any one of both surfaces of the resin film 110; a step of discharging a residual material generated during the first depositing step and forming argon, nitrogen, and oxygen atmospheres using a process gas within the chamber 210 in which the vacuum is formed; and a second depositing step of depositing the chromium oxide layer 130 on the metal texture layer 120.

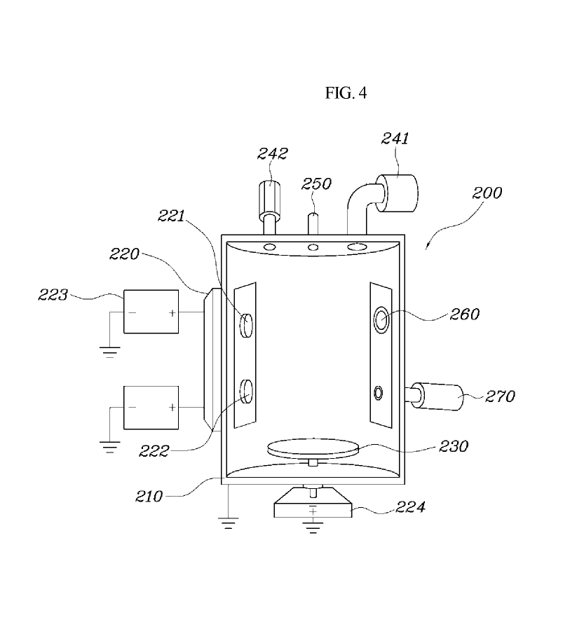

As described above in a description for the metal texture coating for transmitting an electric wave and as shown in FIGS. 1 and 4, a film formed of a material such as transparent PC, PET, or the like, may be used as the resin film 110. The resin film 110 may be fixed to a rotation table 230 within the chamber 210 for deposition, the vacuum may be applied in the chamber 210 by a general depositing process, argon and nitrogen may be injected through a process gas inlet 250, and tin/indium raw materials 221 for forming the metal texture layer 120 may be deposited on the resin film 110. After the above-mentioned primary deposition ends, a raw material of the metal texture layer 120 and argon and nitrogen gas remaining in the chamber 210 may be discharged to the outside of the chamber 210 to prevent pollution at the time of secondary deposition. Argon (Ar), nitrogen (N₂), and oxygen (O₂) may be supplied again to the chamber 210 in which the vacuum is formed through the process gas inlet 250, and a chromium raw material 222 may be supplied to the chamber 210 and may be deposited on the metal texture layer 120, thereby forming the chromium oxide layer 130, which is a resultant material obtained by a reaction between the chromium and the oxygen. In FIG. 4, the reference numeral 200 shows a deposition apparatus.

In addition, in the second depositing step, a ratio of the O₂ to the process gas may be of about 7 wt % or greater

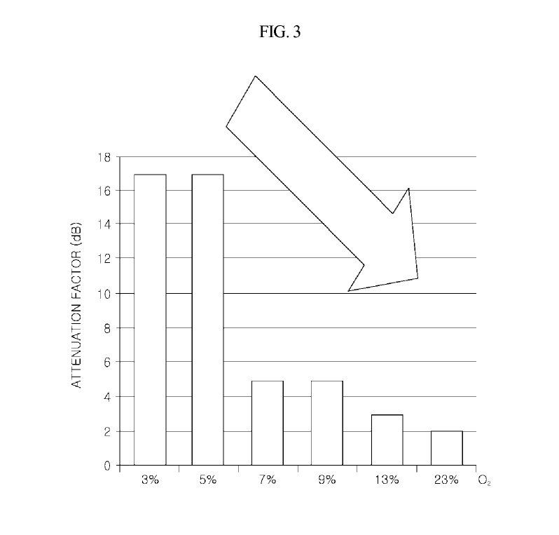

As shown in FIG. 3, an attenuation factor of the electric wave of the chromium oxide layer 130 may be influenced by a ratio of O₂ to the process gas. Particularly, since the attenuation factor may decreased by about 70% as a ratio of O₂ is changed from 5 mol % to 7 mol %, the ratio of O₂ may be limited to 7 mol % or greater. The attenuation factor of the electric wave may be decreased depending on the ratio of O₂, since a chromium oxide may be of a greater portion than chromium in a ratio as being deposited on the metal texture layer 120 when an amount of oxygen reacting to the chromium is increased. When an amount of oxygen is less than the predetermined amount, for example, less than about 7 mol %, chromium atoms may be readily deposited. However, at an atmosphere in which a ratio of the oxygen is in the predetermined amount, for example of about 7 mol %, the chromium oxide may be readily formed by reaction between the chromium and the oxygen. The chromium oxide formed as described above may be deposited on the metal texture layer 120 to form the chromium oxide layer 130. When an oxygen fraction is in the predetermined amount, e.g. 7 mol % or greater, the chromium oxide layer 130 having a decreased attenuation factor of the electric wave may be formed efficiently.

In the first depositing step, the metal texture layer 120 may be formed using one or more of the tin and the indium and may be formed at a thickness of about 150 nm or less. In the second depositing step, the chromium oxide layer 130 may be formed at a thickness of about 1.0 μm or less.

The manufacturing method of a metal texture coating for transmitting an electric wave may further include, before the step of installing the transparent resin film 110, a step of forming the hair line 111 on any one of both surfaces of the resin film 110. The method may further include, after the second depositing step, a step of applying the protecting layer 140 onto the chromium oxide layer 130.

A detailed description for this will be replaced by the description for the metal texture coating for transmitting an electric wave described above.

The metal texture coating for transmitting an electric wave and the manufacturing method thereof according to exemplary embodiments of the present invention have the following effects.

First, metallic gloss property may be maintained even though a thickness of the metal texture layer is reduced.

Second, the chromium oxide having excellent corrosion resistance may be used as a material of the protecting layer, thereby improving corrosion resistance of the coating.

Although exemplary embodiments of the present invention has been described with reference to the accompanying drawings, those skilled in the art will appreciate that various modifications and alterations may be made without departing from the spirit or essential feature of the present invention.

Therefore, it is to be understood that exemplary embodiments described hereinabove are illustrative rather than being restrictive in all aspects. It is to be understood that the scope of the present invention will be defined by the claims rather than the above-mentioned description and all modifications and alternations derived from the claims and their equivalents are included in the scope of the present invention.

What is claimed is:

1. A metal texture coating for transmitting an electric wave, comprising:
a transparent resin film;
a metal texture layer deposited on any one of both surfaces of the resin film; and
a chromium oxide layer deposited on the metal texture layer so as to transmit the electric wave therethrough and protect the metal texture layer.

2. The metal texture coating for transmitting an electric wave of claim 1, wherein the metal texture layer is formed of one or more of tin and indium and has a thickness of about 150 nm or less.

3. The metal texture coating for transmitting an electric wave of claim 1, wherein the chromium oxide layer has a thickness of about 1.0 μm or less.

4. The metal texture coating for transmitting an electric wave of claim 1, wherein a hair line is formed on any one of both surfaces of the resin film.

5. The metal texture coating for transmitting an electric wave of claim 1, further comprising a protecting layer disposed on the chromium oxide layer.

6. A manufacturing method of a metal texture coating for transmitting an electric wave, comprising:
a step of installing a transparent resin film in a chamber for deposition;
a step of forming argon and nitrogen atmospheres using a process gas within the chamber in which vacuum is formed;
a first depositing step of depositing a metal texture layer on any one of both surfaces of the resin film;
a step of discharging a residual material generated during the first depositing step and forming argon, nitrogen, and oxygen (O₂) atmospheres using a process gas within the chamber in which the vacuum is formed; and
a second depositing step of depositing a chromium oxide layer on the metal texture layer.

7. The manufacturing method of a metal texture coating for transmitting an electric wave of claim 6, wherein in the first depositing step, the metal texture layer is formed of one or more of tin and indium, and is formed at a thickness of about 150 nm or less.

8. The manufacturing method of a metal texture coating for transmitting an electric wave of claim 6, wherein in the second depositing step, the chromium oxide layer is formed at a thickness of about 1.0 μm or less.

9. The manufacturing method of a metal texture coating for transmitting an electric wave of claim 8, wherein in the second depositing step, a ratio of the O₂ to the process gas is about 7 mol % or greater.

10. The manufacturing method of a metal texture coating for transmitting an electric wave of claim 6, further comprising, before the step of installing the transparent resin film, a step of forming a hair line on any one of both surfaces of the resin film.

11. The manufacturing method of a metal texture coating for transmitting an electric wave of claim 6, further comprising, after the second depositing step, a step of applying a protecting layer onto the chromium oxide layer.

12. A vehicle part that comprises a metal texture coating of claim 1.
